(19) United States
(12) Patent Application Publication
(10) Pub. No.: US 2024/0334842 A1
(43) Pub. Date: Oct. 3, 2024

(54) Fluoride Passivation of a Cuprate Body

(71) Applicant: The United States of America, as represented by the Secretary of the Navy, San Diego, CA (US)

(72) Inventors: Alexei Smolyaninov, San Diego, CA (US); Teresa Emery-Adleman, San Diego, CA (US); Kyle DiCamillo, San Diego, CA (US); Graham Sanborn, San Diego, CA (US)

(21) Appl. No.: 18/295,157

(22) Filed: Apr. 3, 2023

(51) Int. Cl. H10N 60/01

(52) U.S. Cl. CPC H10N 60/0716; H10N 60/0296

(57) ABSTRACT

A method and apparatus passivates a cuprate body. The cuprate body revealing an unprotected surface is placed in a vessel. The unprotected surface of the cuprate body is exposed to gaseous Xenon Difluoride admitted through a valve into the vessel. During a duration of the exposure, atoms of Fluorine from the gaseous Xenon Difluoride displace atoms of Oxygen in the cuprate body near the unprotected surface. A timer controls a duration of exposing the unprotected surface of the cuprate body to the gaseous Xenon Difluoride admitted into the vessel.

### FEDERALLY SPONSORED RESEARCH AND DEVELOPMENT

The United States Government has ownership rights in this invention. Licensing and technical inquiries may be directed to the Office of Research and Technical Applications, Naval Information Warfare Center Pacific, Code 72120, San Diego, CA, 92152; voice (619) 553-5118; NIWC_Pacific_T2@us.navy.mil. Reference Navy Case Number 210391.

### BACKGROUND OF THE INVENTION

The cuprate group materials, such as Yttrium Barium Copper Oxide, have desirable properties dependent upon the stoichiometry of the constituent elements. This stoichiometry is vulnerable to changing when these materials are subjected to certain environmental conditions and substances, potentially diminishing or destroying the desirable properties. Avoiding these environmental conditions and substances to maintain the desirable properties limits the application environments and the available fabrication processes for manufacturing devices including the cuprate group materials.

### SUMMARY OF THE INVENTION

A method and apparatus passivates a cuprate body. The cuprate body revealing an unprotected surface is placed in a vessel. The unprotected surface of the cuprate body is exposed to gaseous Xenon Difluoride admitted through a valve into the vessel. During a duration of the exposure, atoms of Fluorine from the gaseous Xenon Difluoride displace atoms of Oxygen in the cuprate body near the unprotected surface. A timer controls a duration of exposing the unprotected surface of the cuprate body to the gaseous Xenon Difluoride admitted into the vessel.

### BRIEF DESCRIPTION OF DRAWINGS

Throughout the several views, like elements are referenced using like references. The elements in the figures are not drawn to scale and some dimensions are exaggerated for clarity.

FIG. 1 is a flow diagram of a process for Fluoride passivation of a cuprate body in accordance with an embodiment of the invention.

FIG. 2 is a block diagram of an apparatus for Fluoride passivation of a cuprate body with patterning in accordance with an embodiment of the invention.

FIG. 3 is a flow diagram of a process for Fluoride passivation of a cuprate body with patterning in accordance with an embodiment of the invention.

### DETAILED DESCRIPTION

The disclosed methods and apparatus below may be described generally, as well as in terms of specific examples and/or specific embodiments. For instances where references are made to detailed examples and/or embodiments, it should be appreciated that any of the underlying principles described are not to be limited to a single embodiment, but may be expanded for use with any of the other methods and systems described herein as will be understood by one of ordinary skill in the art unless otherwise stated specifically.

The cuprate group materials have desirable properties, such as the high temperature superconductivity of Yttrium Barium Copper Oxide. However, the transition temperature of the superconductivity of Yttrium Barium Copper Oxide depends strongly on its crystallinity and precise oxygen content. In general, the cuprate group materials are highly susceptible to degradation including deoxygenation, oxygenation, and decomposition, such as decomposition upon exposure to an elevated temperature, water, and water vapor. Such degradation diminishes or destroys the desirable properties, especially for devices that include thin films of the cuprate group materials.

Fluorination of a cuprate can be achieved by treatment with aqueous hydrofluoric acid having 2% to 50% hydrogen fluoride dissolved in water. This fluorination treatment stabilizes the cuprate from subsequent environmental degradation, but exposes the cuprate to water causing degradation of the cuprate during the fluorination treatment, causing immediate degradation with deoxygenation of the surface of the cuprate due to contact with water. This is particularly detrimental for a very thin (e.g. submicron) cuprate film, where degradation extends beneath the surface and across the entire thickness of the cuprate film.

Embodiments of the invention briefly expose the cuprate to gaseous Xenon Difluoride. This forms a fluoride passivation layer without exposing the cuprate to an elevated temperature or environmental contaminants such as water. This novel fluorination treatment not only eliminates restrictions on the environmental conditions of the end-user application of a device containing the cuprate, but also opens up various high temperature and wet fabrication processes for manufacturing such a device. For example, a patterned gold layer typically provides electrical connections to the cuprate, and a layer of gold deposited on the cuprate can be patterned with lithography using aqueous potassium iodide etching without degrading the cuprate due to passivation of the cuprate with gaseous Xenon Difluoride.

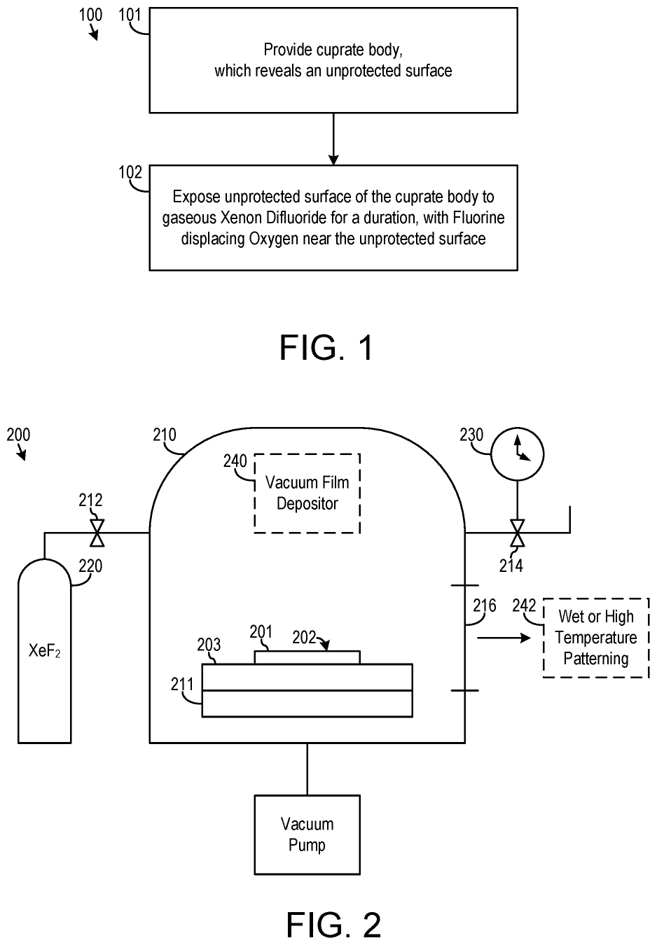

FIG. 1 is a flow diagram of a process 100 for Fluoride passivation of a cuprate body in accordance with an embodiment of the invention.

At step 101, a cuprate body is provided that reveals an unprotected surface. In one example, the cuprate body is a patterned cuprate layer deposited on a substrate, and the unprotected surface is the external surface of the patterned cuprate layer not resting on the substrate. In another example, the cuprate body is the same patterned cuprate layer, but partially covered with a second layer, such as patterned photoresist, and the unprotected surface is the external surface of the patterned cuprate layer neither resting on the substrate nor covered with the second layer.

At step 102, the unprotected surface of the cuprate body is exposed to gaseous Xenon Difluoride for a duration. Xenon Difluoride is a barely stable molecular compound that readily decomposes into stable Xenon atoms and reactive Fluorine atoms. The required temperature needed to activate the decomposition of Xenon Difluoride is below the elevated temperature that starts decomposition of the cuprate body. During this duration of exposure, Fluorine atoms from the Xenon Difluoride diffuse into the cuprate, replacing oxide sites in the crystal lattice with fluoride sites, at a measurable and reproducible rate dependent on the temperature and partial pressure of Xenon Difluoride gas. Thus, atoms of Fluorine from the gaseous Xenon Difluoride displace atoms of Oxygen in the cuprate body near the unprotected surface.

References to each chemical element herein in the specification and claims are defined to mean the chemical element as a member of the periodic table of chemical elements. This definition is emphasized by capitalizing the names of the chemical elements, such as Fluorine and Oxygen. Similarly, references to a molecular compound herein in the specification and claims are defined to mean the named combination of chemical elements. This definition is emphasized by capitalizing the name of the molecular compound, such as Xenon Difluoride consisting of one molar part of the chemical element Xenon and two molar parts of the chemical element Fluorine.

Returning to step 101, providing of the cuprate body includes providing the cuprate body consisting of multiple chemical elements including Oxygen. The unprotected surface of the cuprate body becomes a passivated surface during the exposure for the duration because the atoms of Fluorine bind to atoms of one or more of the other chemical elements more strongly than the atoms of displaced Oxygen were bonded to these atoms of these other chemical elements. For example in Yttrium Barium Copper Oxide, the Barium Fluoride bonds achieved after treatment are stronger than the replaced Barium Oxide bonds.

Furthermore, the higher electronegativity of Fluorine as compared to Oxygen provides a diffusion barrier that inhibits or prevents movement of atoms of Oxygen past the atoms of Fluorine. Thus, atoms of Fluorine bonded near an exposed surface of the cuprate body inhibits or prevents diffusion of atoms of Oxygen either into or out of the cuprate body.

In one example, the unprotected surface of the cuprate body before the exposure is vulnerable to degrading with loss of Oxygen near the unprotected surface and beyond when subjected to environmental conditions including an elevated temperature, a vacuum, and/or a reducing atmosphere. However, the passivated surface after the exposure for the duration protects the cuprate body from degrading when subjected to such environmental conditions.

In another example, the unprotected surface of the cuprate body before the exposure is vulnerable to accumulating Oxygen near the unprotected surface and beyond when subjected to environmental conditions including an elevated temperature and an atmosphere with Oxygen. However, the passivated surface after the exposure for the duration protects the cuprate body from degrading by accumulating Oxygen when subjected to such environmental conditions.

In yet another example, the unprotected surface of the cuprate body before the exposure is vulnerable to degrading upon contact with environmental substances including gaseous and liquid water. However, the passivated surface after the exposure for the duration protects the cuprate body from degrading upon contact with such environmental substances.

In summary, the unprotected surface of the cuprate body before the exposure is vulnerable to degrading upon encountering environmental conditions and environmental substances, but during the exposure for the duration, the unprotected surface becomes a passivated surface, which protects the cuprate body from degrading upon encountering the environmental conditions and the environmental substances.

In one embodiment, providing of the cuprate body at step 101 includes providing the cuprate body consisting essentially of Yttrium Barium Copper Oxide. In another embodiment, the cuprate body consists of multiple elements, which consist essentially of Oxygen, Copper, and at least one a rare earth element, such as one or more rare earth elements in ionization state +1, +2, and/or +3. In yet another embodiment, the cuprate body is a high temperature superconductor.

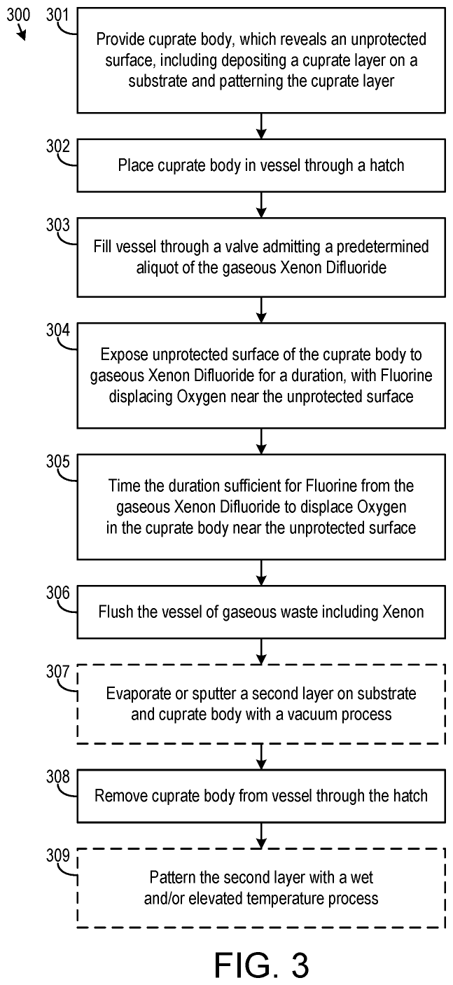

FIG. 2 is a block diagram of an apparatus 200 for Fluoride passivation of a cuprate body 201 with patterning in accordance with an embodiment of the invention. In one embodiment, the apparatus 200 uses the process 100 of Fluoride passivation of FIG. 1 or the process 300 of Fluoride passivation of FIG. 3, which is discussed below.

The apparatus 200 includes a vessel 210 into which the cuprate body 201 is placed before exposure, the cuprate body 201 revealing an unprotected surface 202. A temperature regulator 211, such as a heater controlled by a thermocouple, sets the temperature of the cuprate body 201 sufficient to activate the decomposition of gaseous Xenon Difluoride, but without setting the temperature of the cuprate body 201 so high as to start decomposition of the cuprate body 201. A valve 212 admits the gaseous Xenon Difluoride from a supply cylinder 220 into the vessel 210 to begin the exposure. During the exposure, atoms of Fluorine from the gaseous Xenon Difluoride displace atoms of Oxygen in the cuprate body 201 near its unprotected surface 202. It will be appreciated that Fluorine from the gaseous Xenon Difluoride might also form fluoride compounds with elements of the cuprate body 201 without displacing Oxygen, and the Fluorine from the gaseous Xenon Difluoride bonds both at the unprotected surface 202 of the cuprate body 201 and inside the cuprate body 201 via diffusion near the unprotected surface 202.

A timer 230 controls the duration of the exposure of the unprotected surface 202 of the cuprate body 201 to the gaseous Xenon Difluoride admitted into the vessel 210. For example, the timer 230 opens an exhaust valve 214 upon expiration of the exposure duration.

In one embodiment, the valve 212 admits a predetermined aliquot of the gaseous Xenon Difluoride into the vessel 210 to begin the exposure. The timer 230 controls the exposure duration sufficient for the atoms of Fluorine from the predetermined aliquot of the gaseous Xenon Difluoride to displace atoms of Oxygen in the cuprate body 201 near the unprotected surface 202.

In one embodiment, the vessel 210 has a hatch 216 for placing the cuprate body 201 into the vessel 210 before starting the timer 230 for the duration of the exposure, and for removing the cuprate body 201 from the vessel 210 after the timer 230 indicates the end of the duration of the exposure.

In one embodiment, the vessel 210 is also used for depositing a layer on the passivated cuprate body 201. For example, vacuum film depositor 240 evaporates or sputters an aluminum layer on the passivated cuprate body 201 and the substrate 203. Subsequently after removing the passivated cuprate body 201 with substrate 203 from the vessel 210 via the hatch 216, film pattering 242 patterns the deposited layer with a wet process or an elevated temperature process, or both. An example of a wet process is dissolving the deposited layer with an acid through openings in a photomask, and an example of an elevated temperature process is plasma etching. Because the Fluorine treatment passivates the cuprate body 201, the vacuum of the vacuum film depositor 240 and the water and/or reactive chemicals in the film pattering 242 do not degrade the cuprate body 201.

FIG. 3 is a flow diagram of a process 300 for Fluoride passivation of a cuprate body with patterning in accordance with an embodiment of the invention.

At step 301, a cuprate layer is deposited on a substrate and the cuprate layer is patterned into the cuprate body before the exposure. The cuprate body reveals an unprotected surface. At step 302, the cuprate body is placed through a hatch into a vessel before beginning the exposure.

At step 303, the vessel is filled with the gaseous Xenon Difluoride to begin the exposure. In one embodiment, this includes admitting a predetermined aliquot of the gaseous Xenon Difluoride into the vessel. At step 304, the unprotected surface of the cuprate body is exposed to gaseous Xenon Difluoride for a duration, with Fluorine displacing Oxygen near the unprotected surface. In one embodiment, the duration of the exposure is timed at step 305, including waiting for the atoms of Fluorine from the predetermined aliquot of the gaseous Xenon Difluoride to displace atoms of Oxygen in the cuprate body near the unprotected surface. At step 306, gaseous waste including Xenon is flushed from the vessel after the exposure. At step 308, the cuprate body is removed from the vessel through the hatch after the exposure.

At optional step 307, after exposing the unprotected surface of the cuprate body patterned from the cuprate layer at step 304, a second layer is deposited on the substrate and the cuprate body with a vacuum process. For example, the second layer is a conductive layer of evaporated or sputtered aluminum, copper, or gold. At optional step 309, the second layer is patterned with a wet or elevated temperature process. The processes of steps 307 and 309 would each degrade the cuprate body if performed before the exposure at step 304, but instead the processes of steps 307 and 309 do not degrade the passivated cuprate body.

From the above description of Fluoride Passivation of a Cuprate Body, it is manifest that various techniques may be used for implementing the concepts of methods 100 and 300 and apparatus 200 without departing from the scope of the claims. The described embodiments are to be considered in all respects as illustrative and not restrictive. Each of methods 100 or 300 or apparatus 200 disclosed herein may be practiced in the absence of any element that is not specifically claimed and/or disclosed herein. It should also be understood that each of methods 100 or 300 or apparatus 200 is not limited to the particular embodiments described herein, but is capable of many embodiments without departing from the scope of the claims.

We claim:

1. A method of passivation of a cuprate body, comprising:
providing the cuprate body that reveals an unprotected surface; and
exposing the unprotected surface of the cuprate body to gaseous Xenon Difluoride for a duration, wherein a first plurality of atoms of Fluorine from the gaseous Xenon Difluoride displace a second plurality of atoms of Oxygen in the cuprate body near the unprotected surface.

2. The method of claim 1, wherein
the providing of the cuprate body includes providing the cuprate body consisting of a plurality of chemical elements including the Oxygen; and
the unprotected surface of the cuprate body becomes a passivated surface during the exposing for the duration because the first atoms of Fluorine bind to a third plurality of atoms of at least one of the chemical elements more strongly than the second atoms of displaced Oxygen were bonded to the third atoms of said at least one of the chemical elements.

3. The method of claim 2, wherein the unprotected surface of the cuprate body before the exposing is vulnerable to degrading with loss of Oxygen near the unprotected surface and beyond when subjected to environmental conditions including elevated temperature, a vacuum, and a reducing atmosphere, but the passivated surface after the exposing for the duration protects the cuprate body from degrading when subjected to the environmental conditions.

4. The method of claim 2, wherein the unprotected surface of the cuprate body before the exposing is vulnerable to accumulating Oxygen near the unprotected surface and beyond when subjected to environmental conditions including an atmosphere including Oxygen, but the passivated surface after the exposing for the duration protects the cuprate body from accumulating Oxygen when subjected to the environmental conditions.

5. The method of claim 2, wherein the unprotected surface of the cuprate body before the exposing is vulnerable to degrading upon contact with environmental substances including gaseous and liquid water, but the passivated surface after the exposing for the duration protects the cuprate body from degrading upon contact with the environmental substances.

6. The method of claim 1, wherein the unprotected surface of the cuprate body before the exposing is vulnerable to degrading upon encountering environmental conditions and environmental substances, but during the exposing for the duration the unprotected surface becomes a passivated surface, which protects the cuprate body from degrading upon encountering the environmental conditions and the environmental substances.

7. The method of claim 1, wherein the providing of the cuprate body includes providing the cuprate body consisting essentially of Yttrium Barium Copper Oxide.

8. The method of claim 1, wherein the providing of the cuprate body includes providing the cuprate body that is a high temperature superconductor.

9. The method of claim 1, wherein the providing of the cuprate body includes providing the cuprate body consisting of a plurality of elements, which consist essentially of the Oxygen, Copper, and at least one a rare earth element.

10. The method of claim 9, wherein said at least one a rare earth element is in ionization state +1, +2, and/or +3.

11. The method of claim 1, further comprising:
placing the cuprate body into a vessel before the exposing;
filling the vessel with the gaseous Xenon Difluoride to begin the exposing; and
removing the cuprate body from the vessel after the exposing.

12. The method of claim 11, wherein:
the filling includes admitting a predetermined aliquot of the gaseous Xenon Difluoride into the vessel;
the exposing for the duration includes waiting for the first atoms of Fluorine from the predetermined aliquot of the gaseous Xenon Difluoride to displace the second atoms of Oxygen in the cuprate body near the unprotected surface; and
the removing includes flushing the vessel of gaseous waste including Xenon.

13. A method of patterning that incorporates the method of passivation of claim 1, wherein:
the providing includes depositing a cuprate layer on a substrate and patterning the cuprate layer into the cuprate body before the exposing; and
the method of patterning includes, after the exposing of the unprotected surface of the cuprate body patterned from the cuprate layer, depositing a second layer on the substrate and the cuprate body with a vacuum process and patterning the second layer with a wet or elevated temperature process, wherein the vacuum process and the wet or elevated temperature process would each degrade the cuprate body if performed before the exposing, but instead the processes do not degrade the cuprate body.

14. The method of patterning of claim 13, wherein the second layer is a conductive layer of aluminum, copper, or gold.

15. An apparatus for passivation of the cuprate body using the method of passivation of claim 1, comprising:
a vessel, wherein the providing includes placing the cuprate body into the vessel before the exposing;
a valve for admitting the gaseous Xenon Difluoride into the vessel to begin the exposing; and
a timer for controlling the duration of the exposing of the unprotected surface of the cuprate body to the gaseous Xenon Difluoride admitted into the vessel, wherein the first atoms of Fluorine from the gaseous Xenon Difluoride displace the second atoms of Oxygen in the cuprate body near the unprotected surface.

16. The apparatus of claim 15, comprising:
the valve for admitting a predetermined aliquot of the gaseous Xenon Difluoride into the vessel to begin the exposing; and
the timer for controlling the duration sufficient for the first atoms of Fluorine from the predetermined aliquot of the gaseous Xenon Difluoride to displace the second atoms of Oxygen in the cuprate body near the unprotected surface.

17. The apparatus of claim 16, wherein the vessel has a hatch for placing the cuprate body into the vessel before the exposing, and for removing the cuprate body from the vessel after the exposing.

18. An apparatus for passivation of a cuprate body, comprising:
a vessel into which the cuprate body is placed, the cuprate body revealing an unprotected surface;
a valve for admitting gaseous Xenon Difluoride into the vessel; and
a timer for controlling a duration of exposing the unprotected surface of the cuprate body to the gaseous Xenon Difluoride admitted into the vessel, wherein a first plurality of atoms of Fluorine from the gaseous Xenon Difluoride displace a second plurality of atoms of Oxygen in the cuprate body near the unprotected surface.

19. The apparatus of claim 18, comprising:
the valve for admitting a predetermined aliquot of the gaseous Xenon Difluoride into the vessel; and
the timer for controlling the duration sufficient for the first atoms of Fluorine from the predetermined aliquot of the gaseous Xenon Difluoride to displace the second atoms of Oxygen in the cuprate body near the unprotected surface.

20. The apparatus of claim 19, wherein the vessel has a hatch for placing the cuprate body into the vessel before starting the timer for the duration, and for removing the cuprate body from the vessel after the timer indicates ending of the duration.
